(19) United States
(12) Patent Application Publication
(10) Pub. No.: US 2015/0200078 A1
(43) Pub. Date: Jul. 16, 2015

(54) PLASMA ETCHING APPARATUS

(71) Applicant: ULVAC, INC., Kanagawa (JP)

(72) Inventor: Yasuhiro MORIKAWA, Susono-shi (JP)

(21) Appl. No.: 14/671,911

(22) Filed: Mar. 27, 2015

Related U.S. Application Data
(63) Continuation of application No. 13/498,376, filed on Mar. 27, 2012.

(30) Foreign Application Priority Data
Sep. 29, 2009 (JP) 2009-225434

(51) Int. Cl. H01J 37/32; C23F 4/00

(52) U.S. Cl. CPC H01J 37/3266; C23F 4/00; H01J 37/3211; H01J 2237/334

(57) ABSTRACT

A method for etching a substrate with plasma, including: holding a substrate on a substrate stage; forming an annular zero magnetic field region lying along a circumferential direction of an inner side of a middle-stage coil of three stages of concentrically-arranged magnetic field coils; supplying-etching gas to an interior of a chamber main body; supplying high frequency power to a high-frequency antenna and an electrode to form an induced electric field in the zero magnetic field region to generate plasma; and etching the substrate with the plasma. Forming an annular zero magnetic field region includes forming the region in a state in which the chamber main body is internally inserted from an inner side of a lowermost stage coil of the magnetic field coils to the inner side of the middle-stage coil so that the zero magnetic field region is formed near an inner surface of the top part.

### RELATED APPLICATIONS

The present application is a continuation of U.S. patent application Ser. No. 13/498,376, filed Mar. 27, 2012, which is a National Phase entry of PCT Application No. PCT/JP2010/064155, filed Aug. 23, 2010, which claims priority from Japanese Patent Application Number 2009-225434, filed Sep. 29, 2009, the disclosures of which are hereby incorporated by reference herein in their entireties.

### TECHNICAL FIELD

The present invention relates to a plasma etching device, more particularly, to a device that generates plasma using an annular zero magnetic field region in which a magnetic flux density becomes “0”, namely, etches using a so-called zero magnetic field region discharge plasma.

### BACKGROUND ART

In the prior art, for example, as described in patent document 1, a known plasma etching device includes three stages of magnetic field coils, which are wound around an outer circumference of a cylindrical container, and a high frequency antenna, which is arranged at an inner side of the magnetic field coil located at the middle stage of the three stages of magnetic field coils and which has a center that is coaxial with the center of the magnetic field coils. In such plasma etching device, when current is supplied to the upper stage and the lower stage coils of the magnetic field coils in the same direction, and a current is supplied to the middle stage coil in an opposite direction, an annular zero magnetic field region in which the magnetic flux density becomes “0” is generated in a space in the container inward in a radial direction from the middle stage coil. In this case, when high frequency power is supplied to the high frequency antenna arranged at the inner side of the magnetic field coils, the gas supplied in the container is plasmatized, and plasma having a particularly high density is generated by electrons gathered along a magnetic gradient in the zero magnetic field region. Thus, a so-called magnetic neutral discharge plasma, which is plasma induced in the container, has a higher density than a so-called inductive coupling plasma, which is plasma induced only by the high frequency antenna and without the magnetic field coil.

The zero magnetic field region may change the size of its diameter by changing the ratio of the current supplied to the upper stage and lower stage coils and the current supplied to the middle stage coil. Specifically, when the supplying power to the upper stage and lower stage coils is fixed, the diameter of the zero magnetic field region is reduced by increasing the current supplied to the middle stage coil, and the diameter of the zero magnetic field region is enlarged by decreasing the current supplied to the middle stage coil. The uniformity of the speed of etching performed by the plasma etching device and the in-plane etching speed in an etching subject, for example, a substrate, is known to be dependent on the diameter of the zero magnetic field region. In other words, in the plasma etching device, the uniformity of the etching speed may be guaranteed in the substrate plane by adjusting the current supplied to the magnetic coils to realize a size of the diameter of the zero magnetic field region at which the in-plane uniformity of the etching speed would be most guaranteed regardless of the condition of the etching process.

In this manner, the zero magnetic field discharge plasma has properties of high density and enabling the in-plane uniformity of the etching speed to be controlled. Thus, the use of the zero magnetic field discharge plasma allows an etching process to be performed with higher etching speed and guaranteed uniformity of the etching speed in the substrate plane.

### PRIOR ART DOCUMENT

Patent Document 1: Japanese Laid-Open Patent Publication No. 8-311667

### SUMMARY OF THE INVENTION

Progress in the etching process performed in the plasma etching device increases the accumulated amount of the particles emitted from the material of the etched substrate, products derived from the reaction of the material of the substrate and the etching gas, dissociated matters from the etching gas, and the like. In addition, these various types of substances, which are carried by the flow of gas in the container, strike and collect on the inner surface of the container.

Such collected matter collected on the inner surface of the container varies the impedance in the container. This, in turn, varies the density and the temperature of the plasma induced in the container. As a result, even when an etching process is performed under conditions similar to those for initial operation of the device, that is, conditions similar to when there is subtle collected matter deposited on the device, the etching process may not be performed at the same speed. Thus, for example, if the etching amount is controlled by the processing time, the desired process cannot be completed even if the etching process is performed on the substrate for the time necessary for a predetermined process. This lowers the yield of the product manufactured by the process.

Further, the collected matter at a location distance from the high frequency coil, in particular, the collected matter on a top part of the cylindrical container may be delaminated from the top part depending on the conditions such as the temperature at which the etching process is performed or the pressure in the device. Some of the collected matters delaminated from the top part collect on the etching processed surface of the substrate, which is the subject of etching. This lowers the yield of the product manufactured through the processing in the plasma etching device.

Accordingly, it is an object of the present invention to provide a plasma etching device that suppresses the deposition of collected matter that collects on the inner surface of the processing container as an etching process advances in the plasma etching device.

One aspect of the present invention is a plasma etching device that etches a substrate with plasma. The plasma etching device is provided with a magnetic field formation unit including at least three stages of magnetic field coils, which are arranged concentrically. The magnetic field formation unit forms an annular zero magnetic field region lying along a circumferential direction of the magnetic coils at an inner side of the magnetic field coil in a middle stage. A chamber main body is internally inserted at the inner side of the magnetic field coils, internally includes the zero magnetic field region, and accommodates the substrate below the zero magnetic field region. The chamber main body includes a top part. A gas supplying unit supplies etching gas to an interior of the chamber main body. A high frequency antenna generates an induced electric field in the zero magnetic field region and generates plasma of the etching gas. An electrode is arranged above the top part of the chamber main body and electrostatically coupled to plasma generated in the chamber main body.

### BRIEF DESCRIPTION OF THE DRAWINGS

FIG. 1 is schematic diagram illustrating a plasma etching device in one embodiment.

FIG. 2 is a plan view illustrating a schematic structure of a top plate, a planar electrode, and a high frequency loop antenna included in the plasma etching device of FIG. 1.

FIG. 3 is a plan view illustrating a schematic structure of the planar electrode included in the plasma etching device of FIG. 1.

FIG. 4 is a plan view illustrating a schematic structure of a planar electrode included in a plasma etching device of a further embodiment.

FIG. 5 is a plan view illustrating a schematic structure of a planar electrode included in a plasma etching device of a further embodiment.

FIG. 6 is a plan view illustrating a schematic structure of a planar electrode included in a plasma etching device of a further embodiment.

### DETAILED DESCRIPTION OF THE EMBODIMENTS

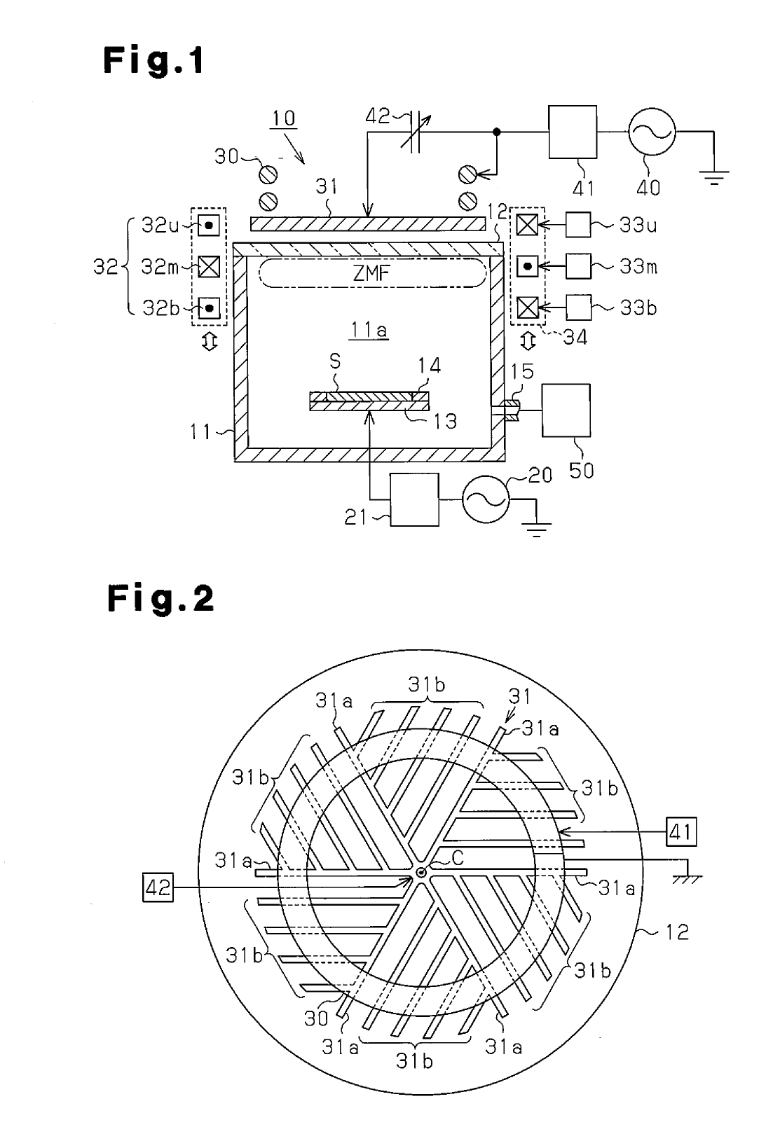

One embodiment of a plasma etching device according to the present invention will now be described with reference to FIGS. 1 to 3.

FIG. 1 is a schematic diagram of a plasma etching device in the present embodiment. As illustrated in FIG. 1, a plasma etching device 10 includes a chamber main body including a chamber bottom part 11, which is cylindrical and has a closed bottom, and a top plate 12 formed from quartz, which is a dielectric. That is, the chamber main body includes the top plate 12 serving as a top part of the chamber main body that covers the upper part of the cylindrical part having a closed bottom. The chamber bottom part 11 and the top plate 12 define a plasma generation region 11a.

In the plasma generation region 11a, a substrate stage 13 is arranged to hold a substrate S, which is a subject of plasma etching process performed in the plasma generation region 11a. A protection member 14 that is resistant to plasma induced in the plasma generation region 11a and various gases that form plasma and protects the substrate stage 13 from corrosion resulting from such substances is arranged on an outer circumference of the substrate stage 13. Glassy carbon or the like having high resistance to chlorine or iodine plasma is used to form the protection member 14.

A bias high frequency power supply 20, which applies a predetermined bias potential to the substrate S held on the substrate stage 13, is electrically connected to the substrate stage 13. A bias matching circuit 21, which impedance-matches the gas in the plasma generation region 11a serving as a load and a transmission path from the bias high frequency power supply 20 to the substrate S, is arranged between the substrate S and the bias high frequency power supply 20.

A high frequency loop antenna 30, which is annular, has ends, and includes two windings, is arranged so that its two ends are adjacent on a plane parallel to the outer surface of the top plate 12. A planar electrode 31 is arranged between the top plate 12 and the high frequency loop antenna 30 parallel to planes on which the top plate 12 and the high frequency loop antenna 30 are arranged.

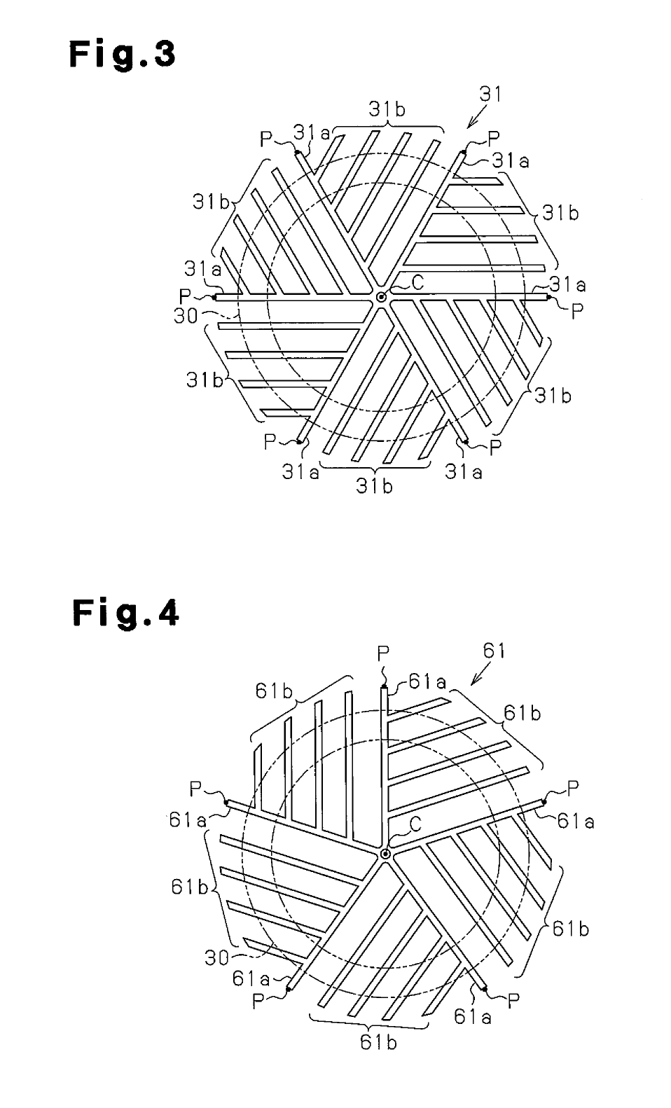

The structure of the top plate 12, the planar electrode 31, and the high frequency loop antenna 30 when viewing their upper surfaces from above will now be described in detail with reference to FIG. 2. In particular, the planar electrode 31 will be described in detail with reference to FIG. 3. As illustrated in FIG. 2, the top plate 12 and the high frequency loop antenna 30 have centers arranged on a center axis C. The planar electrode 31 is also arranged so that its center is located on the center axis C. The high frequency loop antenna 30 has an annular shape that is a similar to the shape of the top plate 12 and the substrate S when seen from an axial direction of the center axis C. Further, the high frequency loop antenna 30 includes an input end connected to a matching circuit 41 and an output end connected to a ground potential.

The planar electrode 31 is formed by metal wires and includes six lines radially extending from its center toward the outer circumference of the top plate 12. Each of the six lines is long enough to extend to the outer side of the top plate 12 outward from the outer circumference of the high frequency loop antenna 30 when seen from the axial direction of the center axis C. In this manner, in the present embodiment, the formation region of the planar electrode 31 extends beyond a range of a region surrounded by the outer circumference of the high frequency loop antenna 30. However, the terminating ends of the lines of the planar electrode 31 radially extending from the center of the planar electrode 31 may be aligned with the outer circumference of the high frequency loop antenna 30.

FIG. 3 is a plan view illustrating the structure of the planar electrode 31. In FIG. 3, the planar electrode 31 is illustrated by solid lines, and the high frequency loop antenna 30 is illustrated by double-dashed lines. The planar electrode 31 includes six main lines 31a, which serves as first lines. The main lines 31a are formed by straight lines connecting the vertices P of a regular hexagon inscribed in a hypothetical circle with the terminating ends of the main lines 31a and the center of the hypothetical circle. In other words, the main lines 31a radially extend in the horizontal direction from the center of the hypothetical circle and intersects the high frequency loop antenna 30 at terminating end sides (vertices P) as viewed in an axial direction of the center axis C. The end of each main line 31a on the center axis C is the starting end, and the end of each main line 31a coinciding with the outer circumference of the hypothetical circle is the terminating end.

Each of the main lines 31a includes four branched lines 31b, which serves as second lines. The main lines 31a serve as the bases of branching at which the starting ends of the four branched lines 31b are arranged at equal intervals on each main line 31a. The ends of the branched lines 31b located on the main lines 31a, which are the branching bases, serve as starting ends. The ends of the branched lines 31b aligned with the outer circumference of the planar electrode 31 serve as terminating ends. Each branched line 31b is parallel to one of the two main lines 31a adjacent to the main line 31a that is the branching base of the branched line 31b. Further, the branched lines 31b branched from each main line 31a are arranged in a region in which the branched lines 31b do not intersect with the branched lines 31b of the adjacent main lines 31a. The terminating ends of the branched lines 31b are located on the hypothetical circle. The branched lines 31b closer to the terminating ends of the main lines 31a are shorter in length, whereas the branched lines 31b closer to the starting ends of the main lines 31a are longer in length.

As illustrated in FIG. 1, three stages of magnetic field coils 32 having coaxial centers are arranged sideward from the upper end of the chamber bottom part 11, that is, in the proximity of the top plate 12 located at the upper end of the tubular part of the chamber main body. The magnetic field coils 32 include an upper stage coil 32u, which is a magnetic field coil of the uppermost stage arranged at a location closer to the planar electrode 31 than the inner surface (i.e., lower surface) of the top plate 12. Further, the magnetic field coils 32 includes a middle stage coil 32m, which is a magnetic field coil of the middle stage arranged on a plane flush with the inner surface of the top part of the chamber main body, that is, the inner surface of the top plate 12 in the present embodiment. Further, the magnetic field coils 32 includes a lower stage coil 32b, which is a magnetic field coil of the lowermost stage arranged at a location closer to the substrate stage 13 than the middle stage coil 32. That is, the tubular chamber bottom part 11 is inserted from the inner side of the lower stage coil 32b to the inner side of the middle stage coil 32m.

The three coils 32u, 32m, and 32b are respectively supplied with current from power supplying units 33u, 33m, and 33b so that the upper stage coil 32u and the lower stage coil 32b are supplied with current flowing in the same direction and the middle stage coil 32m is supplied with current flowing in a direction opposite to the current supplied to the upper stage coil 32u and the lower stage coil 32b. This forms an annular zero magnetic field region ZMF at the inner side of the middle stage coil 32m along the circumferential direction of the magnetic field coils 32, that is, along the inner circumferential surface of the chamber bottom part 11. In other words, the zero magnetic field region ZMF is included in the plasma generation region 11a defined by the chamber main body and is covered by the inner surface of the top plate 12 located on in the same plane as the arrangement plane of the middle stage coil 32m. The three stages of magnetic field coils 32 and the power supplying units 33u, 33m, and 33b function as a magnetic field formation unit.

A position changing device 34, which serves as a position changing means for moving the magnetic field coils 32 in the stage direction of the magnetic field coils 32 to change the locations of the magnetic field coils 32, is connected to the three stages of the magnetic field coils 32. The position changing device 34 is formed by an actuator such as a motor and moves along a shaft arranged in the stage direction to move the magnetic field coil 32. When the position changing device 34 moves the magnetic field coils 32, the position of the magnetic field coils 32 relative to the high frequency loop antenna 30, that is, the position of the zero magnetic field region ZMF relative to the inner surface of the top plate 12 is changed.

A high frequency power supply 40 is electrically connected to the high frequency loop antenna 30. A matching circuit 41 is arranged between the high frequency power supply 40 and the high frequency loop antenna 30. The matching circuit 41 impedance-matches the plasma generation region 11a, which serves as a load, and the transmission path from the high frequency power supply 40 to the chamber main body through the high frequency loop antenna 30. The output side of the matching circuit 41 is connected to the center of the planar electrode 31 through a variable capacitor 42. The electrostatic capacitance of the variable capacitor 42 may be freely changed within a range of, for example, 10 pF to 100 pF.

The chamber bottom part 11 includes a gas inlet 15, which draws in etching gas serving as the material of plasma into the plasma generation region 11a. The gas inlet 15 is connected to a gas supplying unit 50 that supplies various types of etching gas corresponding to the plasma etching process performed in the plasma etching device 10. A discharge device (not illustrated) that regulates the interior of the plasma generation region 11a to a predetermined pressure is also connected to the chamber bottom part 11.

When the plasma etching process is performed on the substrate S, which is the processing subject, in the plasma etching device 10, the substrate S is first loaded from a loading port arranged in the plasma etching device 10 and placed on the substrate stage 13. Etching gas is then supplied from the gas supplying unit 50 to the plasma generation region 11a at a flow rate corresponding to the plasma etching process conditions. When the etching gas is supplied to the plasma generation region 11a, the discharge device regulates the interior of the plasma generation region 11a to a pressure corresponding to the plasma etching process conditions. The supplying of the etching gas from the gas supplying unit 50 and the discharge of the etching gas from the plasma generation region 11a by the discharge device are continued as long as the plasma etching process is performed. This cooperation maintains the interior of the plasma generation region 11a at a predetermined pressure.

Current flowing in the same direction is supplied to the upper stage coil 32u and the lower stage coil 32b of the magnetic field coils 32, and current flowing in the opposite direction is supplied to the middle stage coil 32m so that the zero magnetic field region ZMF is formed in the plasma generation region 11a generated at the inner side of the middle stage coil 32m inside the chamber main body. Then, high frequency power of, for example, 13.56 MHz is supplied from the high frequency power supply 40 to the high frequency loop antenna 30 through the matching circuit 41. When the high frequency power is supplied to the high frequency loop antenna 30, an induced electric field is generated in the zero magnetic field region ZMF, and plasma formed from the etching gas is induced. Here, high frequency power is also supplied to the planar electrode 31 so that the planar electrode 31 and the plasma generated in the plasma generation region 11a are electrostatically coupled through ambient air and the top plate 12. The electrostatic capacitance of ambient air and the top plate 12 is normally extremely large compared to the electrostatic capacitance of the plasma generation region 11a. Thus, the potential difference distributed to each capacity component between the planar electrode 31 and the plasma becomes the largest at the inner surface of the top plate 12. The planar electrode 31 having such an effect has a shape that radially spreads from the center axis C. Hence, the electric field generated on the inner surface of the top plate 12 also uniformly spreads over its entire inner surface.

Then, high frequency power of, for example, 13.56 MHz is supplied from the bias high frequency power supply 20 to the substrate S so that a bias voltage corresponding to the high frequency power is applied to the substrate S. The active species, in particular, positive ions present in the plasma generation region 11a are drawn to the substrate S to function as an etchant by the bias voltage applied to the substrate S. This etches a predetermined region of the substrate S along its thickness direction.

When the plasma etching process is performed on the substrate S as described above, the accumulated amount of particles emitted from the material of the substrate S, which is the processing subject, the products derived from the reaction between the configuring material of the substrate S and the etching gas, and dissociated matter from the etching gas increases as the plasma etching process advances. In addition, these various types of substances, which are carried by the flow of gas resulting from the gas supplied by the gas supplying unit 50 and the discharge of gas by the discharge device, strike on the inner surface of the chamber main body. In this case, in the prior art structure in which the high frequency loop antenna is arranged along the outer circumferential surface of the chamber main body as described above, the various types of substances generated in the etching process collect on the inner surface of the chamber main body. In particular, the collected matter is apt to deposit on the top part of the chamber main body, which is a portion distant from the high frequency loop antenna. Moreover, the collected matter deposited on the top part may be delaminated from the top part depending on conditions such as the temperature during the plasma etching process performed in the chamber main body, the inner pressure of the chamber main body, and the like. This may contaminate the substrate S.

In this regards, in the present embodiment, the high frequency loop antenna 30 is arranged above the top plate 12, which is the top part of the chamber main body. Thus, the inner surface of the top plate 12 forming the top part of the chamber main body becomes a negative potential with respect to the plasma due to the capacitive coupling of the plasma generated in the chamber main body and the high frequency loop antenna 30, and thus the positive ions in the plasma strike the inner surface of the top plate 12. Thus, even if etching products or delaminated matter from the etching gas collect on the inner surface of the top plate 12, they are removed from the inner surface of the top plate 12 by the striking of the positive ions, that is, the so-called sputtering. In this manner, in the present embodiment, the plasma etching process is performed while suppressing the deposition of various types of collected matters on the top plate 12.

Further, the portion surrounding the plasma of the chamber main body is located at the lower side of the middle stage coil 32m because the middle stage coil 32m of the magnetic field coils 32 is located on the same plane as the lower surface of the top plate 12. The collected matter described above is normally deposited over the entire portion surrounding the plasma of the chamber main body. Thus, when suppressing variations in the impedance of the container containing the collected matter, it is desired that the area of the region where the collected matters are deposited, that is, the portion surrounding the plasma of the chamber main body be reduced. However, in order for the speed and the uniformity of etching in the substrate S to be guaranteed, as well as for damage to the substrate S by plasma to be avoided, the distance between the zero magnetic field region ZMF and the substrate S becomes limited to a predetermined range such that the plasma density becomes relatively high. That is, even when reducing the area of the portion surrounding the plasma of the chamber main body, the inner surface of the chamber main body is inevitably arranged in a predetermined area between the inner side of the middle stage coil 32m and the substrate S to form the zero magnetic field region ZMF. In this regards, with the structure described above, the uppermost position of the space for generating the plasma, that is, the interior space of the chamber main body is located at the lower side of the upper stage coil 32u. This reduces the area of the region in which collected matter may be deposited, that is, the inner surface of the chamber main body, compared to the structure of the prior art that generates the plasma over the entire region from the lower stage coil 32b to the upper stage coil 32u.

Even in the structure of the prior art in which the high frequency loop antenna is arranged on the outer circumferential part of the chamber main body having a tubular shape, the deposition of the collected matter on the surface of the inner circumferential part corresponding to the outer circumferential part may be suppressed by the sputtering effect. For the plasma used in etching to be in the same state, that is, for the induced electric field generated in the zero magnetic field region ZMF to be the same, the amount of sputtering for removing the collected matters becomes substantially the same in a structure in which the high frequency antenna is arranged at a portion close to the zero magnetic field region ZMF regardless of whether the high frequency loop antenna is arranged at the outer circumferential part of the chamber main body as in the prior art or whether it is arranged above the top plate 12 of the chamber main body as in the present embodiment. However, if the region where the collected matters are deposited is reduced by forming the plasma generation region 11a at the lower side of the middle stage coil 32m as described above, the influence of the collected matter on the plasma may be further reduced thereby suppressing changes in the plasma state.

Further, when the high frequency power is supplied to the high frequency loop antenna 30 and the substrate S, and the plasma etching process is performed, the high frequency power is also supplied to the planar electrode 31. This forms a uniform electric field on the inner surface of the top plate 12, and the bias of sputtering caused by capacity components between the high frequency loop antenna 30 and the plasma is reduced. As a result, the collected matter may be removed even in a region in which the collected matter may not be removed with only the high frequency loop antenna 30. In other words, the area in which various types of products collect on the top plate 12 may be further reduced.

Further, as illustrated in FIGS. 2 and 3, the planar electrode 31 includes six main lines 31a. The main lines 31a are arranged to intersect the high frequency loop antenna 30. Thus, the planar electrode 31 is evenly arranged even in a region in which the high frequency loop antenna 30 is not arranged in the top plate 12. As a result, the sputtering effect of the electrostatic coupling of the plasma and the planar electrode 31, which is arranged between the top plate 12 and the high frequency loop antenna 30, becomes more uniform in the plane of the inner surface of the top plate 12. In other words, the collection of various types of products, such as the etching product and the etching gas dissociated matter, on the inner surface of the top plate 12 may be suppressed without being biased to a specific region in the inner surface. In addition, the branched lines 31b are branched from each of the main lines 31a. In other words, the lines (branched lines 31b) forming the planar electrode 31 are also arranged in regions between the adjacent main lines 31a. This increases the region for capacitive coupling with the plasma in the chamber main body, and the region in which negative potential is applied to the inner surface of the top plate 12 by the planar electrode 31 increases. In other words, the deposition of the collected matter to the inner surface may be suppressed in a further ensured manner by sputtering the entire inner surface of the top plate 12.

In addition, in the present embodiment, the position changing device 34, which moves the three stages of magnetic field coils 32, is used. Thus, the position of the zero magnetic field region ZMF, which is arranged inside the chamber bottom part 11, relative to the electric field generated by the high frequency loop antenna 30 may be changed. That is, the amount of sputtering with respect to the inner surface of the top plate 12 may be changed by both the high frequency loop antenna 30 and the magnetic field coil 32 since the plasma density in the vicinity of the top plate 12 may be changed. Thus, the degree of freedom may be increased compared to a structure in which the range and the amount of removed collected matter in the top plate 12 are changed only by the output of the high frequency loop antenna 30.

The plasma etching device of the present embodiment has at least the advantages described below.

(1) The high frequency loop antenna 30 is arranged above the upper surface of the top plate 12, which is the top part of the chamber main body, that is, the outer surface of the top plate 12. Thus, the inner surface of the top plate 12 becomes a negative potential with respect to the plasma, and positive ions in the plasma strike the inner surface of the top plate 12 due to the capacitive coupling of the plasma generated in the chamber bottom part 11 and the high frequency loop antenna 30. In other words, the plasma etching process may be performed while suppressing the deposition of various types of collected matter on the inner surface of the top plate by removing collected matter from the inner surface of the top plate 12 by the striking of the positive ions, namely, the so-called sputtering.

(2) The middle stage coil 32m of the magnetic field coils 32 is located on a plane on which the top plate 12 is arranged. Thus, the uppermost position of the plasma generation region 11a, which is the space for generating the plasma, that is, the internal space of the chamber bottom part 11, is located at the lower side of the upper stage coil 33u. This decreases the region in which collected matter is deposited compared to the prior art structure that generates plasma over the entire region from the lower stage coil to the upper stage coil so that the influence of the collected matters on the plasma is reduced and variations in the plasma state is suppressed.

(3) The planar electrode 31, which extends in a direction intersecting the outer circumferential end of the high frequency loop antenna 30 when seen from the high frequency loop antenna 30, is arranged between the top plate 12 and the high frequency loop antenna 30. Thus, the electrostatic coupling of the planar electrode 31 and the plasma occurs, and a uniform electric field is formed in a region facing the high frequency loop antenna 30 in the vicinity of the inner surface of the top plate 12. As a result, the bias of the sputtering by the capacity components of the high frequency loop antenna 30 and the plasma is reduced in the vicinity of the inner surface of the top plate 12. In other words, collected matter may be removed in even in a region in which the collected matter may not be removed with only the high frequency loop antenna 30. Further, the area in which various types of products collect on the top plate 12 may be reduced.

(4) The planar electrode 31 includes six main lines 31a that radially extend from a center of a hypothetical circle that is concentric with the high frequency loop antenna 30 and intersect the high frequency loop antenna 30. The planar electrode 31 is thus evenly arranged in a region in which the high frequency loop antenna 30 is not arranged in the top plate 12, in particular, the region surrounded by the outer circumference of the high frequency loop antenna 30. Thus, the effect of the sputtering by the electrostatic coupling of the planar electrode 31 and the plasma becomes more uniform in the inner surface of the top plate 12. In other words, the collection of various types of products, such as etching products and etching gas dissociated matter, on the inner surface of the top plate 12 may be suppressed without being biased to a specific region in the inner surface.

(5) In addition, each main line 31a includes four branched lines 31b, which are parallel to one of the two adjacent main lines 31a. The branched lines 31b extending from each main line 31a are arranged in a region where they do not intersect the branched lines 31b of the adjacent main lines 31a. In other words, a line forming the planar electrode 31 is also arranged in a region between the main lines 31a. The region of the planar electrode 31 that is capacitively coupled with the plasma thus increases, and the negative potential applied to the inner surface of the top plate by the planar electrode 31 becomes large. That is, the sputtering of the top plate 12 by the positive ions generated in the plasma generation region 11a is easily produced, and the deposition of the collected matters on the top plate 12 is suppressed in a further ensured manner.

(6) The position changing device 34 moves the three stages of magnetic field coils 32. This allows for the position of the zero magnetic field region ZMF in the chamber bottom part 11 relative to the electric field generated by the high frequency loop antenna 30 to be changed. That is, the amount of sputtering with respect to the inner surface of the top plate 12 may be changed not only by the output of the high frequency loop antenna 30 but also by the magnetic field coil 32 since the plasma density in the vicinity of the top plate 12 may be changed. This increases the degree of freedom.

The present embodiment may be modified as described below.

The variable capacitor 42 arranged between the planar electrode 31 and the matching circuit 41 may be changed in a variable choke.

The frequency of high frequency power output by the high frequency power supply 40 is not limited to 13.56 MHz and may be changed to an frequency such as 2 MHz, 27 MHz, or 100 MHz in accordance with the conditions of the process performed in the plasma etching device 10.

The winding number of the high frequency loop antenna 30 is not limited to two and may be one winding or more than two.

The high frequency loop antenna 30 is circular but may be a loop antenna having a polygonal shape, such as a tetragon, and including vertices. A high frequency loop antenna having such a shape obtains advantage (1) as long as it is electrostatically coupled with the plasma. Further, even when the top plate 12 has a tetragonal or elliptical shape, the deposition of collected matter on the inner surface of the top plate 12 may be further effectively suppressed since the high frequency loop antenna may be shaped in conformance with the top plate 12.

The substrate stage 13 does not have to include the protection member 14.

A flat anti-collection plate, which is formed by a dielectric, containing quartz or a low expansion glass, or ceramic such as alumina, may be arranged on the inner surface of the top plate 12 parallel to the inner surface of the top plate 12 so as to be attached in a removable manner from the plasma etching device 10. That is, the top part of the chamber main body may be formed by the anti-collection plate and the top plate 12, and the lower surface of the anti-collection plate may be the inner surface of the top part of the chamber main body. Instead of arranging only one anti-collection plate on the inner surface of the top plate 12, a plurality of anti-collection plates may be used. Thus, the top plate 12 may be formed so that two or more flat plates are stacked in the stage direction of the magnetic field coil 32. Such an anti-collection plate obtains the advantage described below.

(7) The top part of the chamber main body includes the top plate 12 and the anti-collection plate, which is attached in a removable manner to the inner surface of the top plate 12, that is, two or more flat plates. Thus, etching reactant, dissociated matter of the etching gas, and the like collect on the anti-collection plate.

Positive ions drawn toward the top part of the chamber main body may suppress collection of various types of products regardless of whether the subject the ions strike is the inner surface of the top plate 12 or the lower surface (substrate side surface) of the anti-collection plate. However, the striking of the positive ions also sputters the anti-collection plates and causes a reaction emitting the material of the plates. Thus, the collected matter is removed from the substrate side of the anti-collection plate by continuing the sputtering, and the anti-collection plate itself is consumed and reduced in thickness.

The top plate 12 is formed from quartz, which is a dielectric, and high frequency power supplied to the high frequency loop antenna 30, arranged on the top plate is supplied into the plasma generation region 11a through the top plate 12. Thus, the thickness of the top plate 12 is generally designed so that the high frequency power from the high frequency loop antenna 30 is effectively supplied to the plasma generation region 11a. If such top plate 12 is sputtered whenever the etching process is performed in the plasma etching device 10, and the thickness is varied, the supply efficiency of the high frequency power is also varied and the state of plasma induced in the plasma generation region 11a is also varied.

In the arrangement of the anti-collection plate on the inner side of the top plate 12 described above, various types of collected matter may be prevented from being depositing on the lower surface of the anti-collection plate, and such collected matter may be prevented from collecting on the top plate 12. Further, the thickness of the top plate 12 may be prevented from being reduced by the sputtering. Thus, the condition of the plasma induced in the plasma generation region 11a may be maintained. In addition, the anti-collection plate is attached in a removable manner to the plasma etching device 10. Thus, although sputtered by the positive ions, if the amount of collected matters deposited on the inner surface becomes an amount that influences the impedance of the vacuum chamber containing the plasma or if the thickness of the anti-collection plate is reduced by sputtering thereby affecting the impedance, such influences may be resolved by simply replacing the anti-collection plate. In other words, the collected matter on the plasma etching device 10 may be removed and the stability of the plasma induced in the plasma etching device 10 may be guaranteed just by replacing the anti-collection plate.

The position changing device 34 for displacing the position of the magnetic field coils 32 may be omitted. For instance, the location of the middle stage coil 32m in the magnetic field coils 32 may be fixed on a plane where the top plate 12 is located.

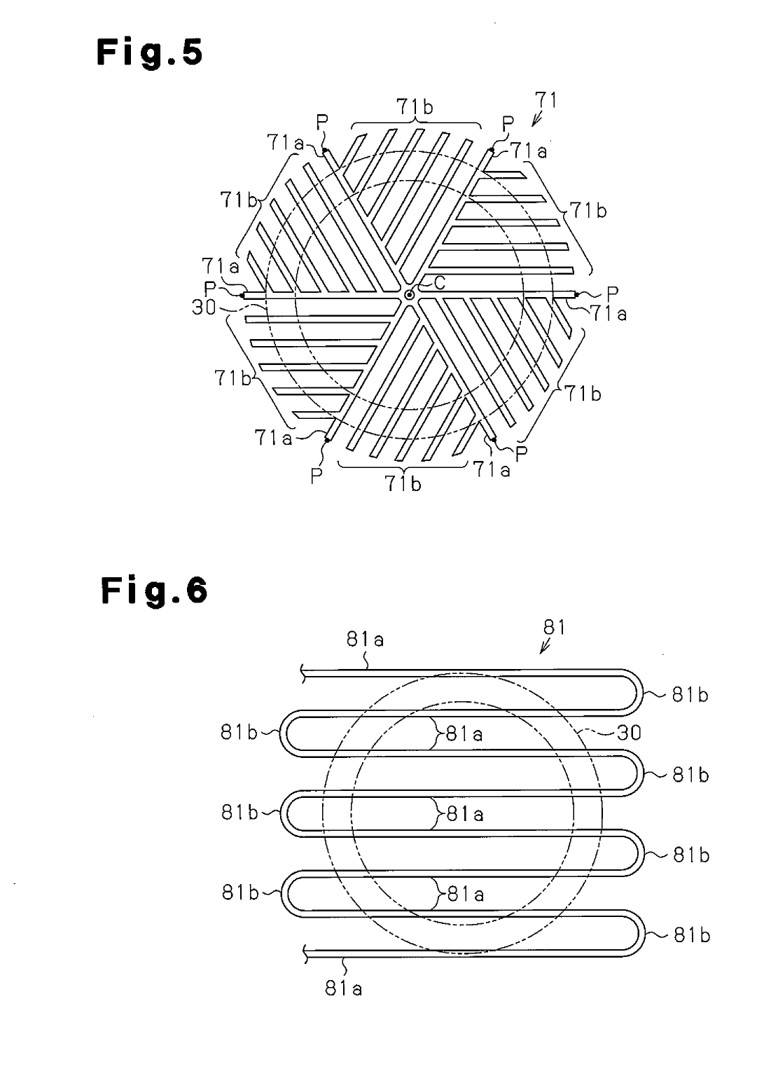

The shape of the planar electrode 31 is not limited to the shape illustrated in FIGS. 2 and 3. For instance, as illustrated in FIG. 4, a planar electrode 61 may include five main lines 61a, which extend on a straight line connecting vertices P of a regular pentagon inscribed in a circle concentric with the high frequency loop antenna 30 and the center of the circle, and four branched lines 61b, which are branched from each of the main lines 61a and are parallel to one of the two main lines 61a adjacent to that main line 61a serving as a branching base. Further, as illustrated in FIG. 5, a planar electrode 71 may include the same number of main lines 71a as the planar electrode 31 and five branched lines 71b branched from each main line 71a. In other words, a planar electrode only needs to include a plurality of main lines, which serve as first lines, on straight lines connecting vertices of a regular polygon, which has four or more corners and inscribed in a circle concentric with the high frequency loop antenna 30′, and a center of the circle, and at least one second line (preferably, a plurality of second lines) branched from each main line.

The branched line 31b of the planar electrode 31 does not have to be parallel to one of the two main lines 31a adjacent to the main line 31a from which it is branched. The planar electrode 31 may include only the main line 31a.

The planar electrode may have a different shape that intersects the outer circumference of the high frequency loop antenna 30 when seen from a direction of the center axis C. For instance, as illustrated in FIG. 6, a planar electrode 81 may include eight main lines 81a, which are parallel line segments. The adjacent main lines 81a are connected by arcuate lines 81b. The planar electrode 81 is arranged so that the main lines 81a intersect the outer circumference of the high frequency loop antenna 30.

In, the example of FIG. 1, the outer circumference of the top plate 12 is located outermost among the high frequency loop antenna 30, the planar electrode 31, and the top plate 12. The outer circumference of the planar electrode 31 comes next and the outer circumference of the high frequency loop antenna 30 is located at the innermost side. However, there is not such limitation, and the outer circumferences of the high frequency loop antenna 30, the planar electrode 31, and the top plate 12 may be arranged in conformance.

The high frequency loop antenna 30 is used as a high frequency antenna, to which the high frequency power is supplied. Instead, a high frequency antenna having a planar spiral shape may be used.

The planar electrode 31, which is arranged between the top plate 12 and the high frequency loop antenna 30, may be omitted. Such a structure also applies negative potential to the inner surface of the top plate 12 with the capacity components of the high frequency loop antenna 30 and the plasma in the vacuum chamber. However, the region to which the negative potential is applied is the region of the top plate 12 immediately below the high frequency loop antenna 30.

In the example of FIG. 1, the middle stage coil 32m is located on a plane same as the inner surface of the top plate 12 of the chamber main body internally inserted to the inner side of the middle stage coil 32m. There is no limitation to such a structure. The inner surface of the top plate 12 may be located between the middle stage coil 32m and the upper stage coil 32u in the direction of the center axis C as long as the chamber main body has a tubular shape allowing for internal insertion of the inner side of the magnetic field coil of the lowermost stage to the inner side of the magnetic field coil of the middle stage, and the inner surface of the top plate 12 covers the zero magnetic field region so that the zero magnetic field region is included in the chamber main body. With such a structure, advantage (2) may be obtained by the extent the inner surface of the top plate 12 is arranged at the lower side of the upper stage coil 32u.

1. A method for etching in a plasma etching device a substrate with plasma, wherein the plasma etching device includes at least three stages of magnetic field coils arranged concentrically, a chamber main body internally inserted at an inner side of the magnetic field coils, a substrate stage arranged in the chamber main body, an electrode arranged above a top part of the chamber main body, a high frequency antenna arranged on the electrode, and a gas supplying unit connected to the chamber main body, the method comprising:
holding the substrate on the substrate stage;
forming an annular zero magnetic field region lying along a circumferential direction of the magnetic field coils at the inner side of a middle stage coil of the magnetic field coils;
supplying-etching gas from the gas supplying unit to an interior of the chamber main body;
supplying high frequency power to the high frequency antenna and the electrode to form an induced electric field in the zero magnetic field region to generate plasma of the etching gas; and
etching the substrate with the plasma generated in the chamber main body,
wherein forming an annular zero magnetic field region includes forming the zero magnetic field region in a state in which the chamber main body is internally inserted from an inner side of a lowermost stage coil of the magnetic field coils to the inner side of the middle stage coil so that there is formed the zero magnetic field region near an inner surface of the top part.

2. The method according to claim 1, wherein the top part of the chamber main body is located below an uppermost stage coil of the magnetic field coils.

3. The method according to claim 1, wherein the high frequency antenna is a loop antenna arranged on the electrode.

4. The method according to claim 1, wherein:
the electrode is formed by a metal wire;
the electrode includes:
a plurality of first lines arranged to connect vertices of a regular polygon, which has four or more corners and which is inscribed in a circle concentric with the high frequency antenna, and a center of the circle, and
a plurality of second lines arranged to branch from each first line and terminating on a circumference of the circle, wherein the second lines are parallel to one of two first lines adjacent to the associated first line, which is a starting point of the branching; and
the plurality of second lines branched from each first line do not intersect the plurality of second lines branched from the adjacent first lines.

5. The method according to claim 1, further comprising displacing the at least three stages of magnetic field coils in a stage direction to change a position of the middle stage coil of the magnetic field coils relative to the high frequency antenna.

6. The method according to claim 1, wherein:
the top part includes two or more flat plates stacked in parallel to a plane on which the magnetic field coils are arranged; and
the one of the two or more flat plates that is closest to the substrate is attached in a removable manner to the chamber main body.

7. The method according to claim 2, wherein the high frequency antenna is a loop antenna arranged on the electrode.

8. The method according to claim 2, wherein:
the electrode is formed by a metal wire;
the electrode includes
a plurality of first lines arranged to connect vertices of a regular polygon, which has four or more corners and which is inscribed in a circle concentric with the high frequency antenna, and a center of the circle, and
a plurality of second lines arranged to branch from each first line and terminating on a circumference of the circle, wherein the second lines are parallel to one of two first lines adjacent to the associated first line, which is a starting point of the branching; and
the plurality of second lines branched from each first line do not intersect the plurality of second lines branched from the adjacent first lines.

9. The method according to claim 2, further comprising displacing the at least three stages of magnetic field coils in a stage direction to change a position of the middle stage coil of the magnetic field coils relative to the high frequency antenna.

10. The method according to claim 2, wherein:
the top part includes two or more flat plates stacked in parallel to a plane on which the magnetic field coils are arranged; and
the one of the two or more flat plates that is closest to the substrate is attached in a removable manner to the chamber main body.

11. The method according to claim 3, wherein:
the electrode is formed by a metal wire;
the electrode includes
a plurality of first lines arranged to connect vertices of a regular polygon, which has four or more corners and which is inscribed in a circle concentric with the high frequency antenna, and a center of the circle, and
a plurality of second lines arranged to branch from each first line and terminating on a circumference of the circle, wherein the second lines are parallel to one of two first lines adjacent to the associated first line, which is a starting point of the branching; and
the plurality of second lines branched from each first line do not intersect the plurality of second lines branched from the adjacent first lines.

12. The method according to claim 3, further comprising displacing the at least three stages of magnetic field coils in a stage direction to change a position of the middle stage coil of the magnetic field coils relative to the high frequency antenna.

13. The method according to claim 3, wherein:
the top part includes two or more flat plates stacked in parallel to a plane on which the magnetic field coils are arranged; and
the one of the two or more flat plates that is closest to the substrate is attached in a removable manner to the chamber main body.

14. The method according to claim 4, further comprising displacing the at least three stages of magnetic field coils in a stage direction to change a position of the middle stage coil of the magnetic field coils relative to the high frequency antenna.

15. The method according to claim 4, wherein:
the top part includes two or more flat plates stacked in parallel to a plane on which the magnetic field coils are arranged; and
the one of the two or more flat plates that is closest to the substrate is attached in a removable manner to the chamber main body.
